(19) United States
(12) Patent Application Publication
(10) Pub. No.: US 2004/0266123 A1
(43) Pub. Date: Dec. 30, 2004

(54) Electron beam treatment of SixNy films

(75) Inventors: Zhenjiang Cui, San Jose, CA (US); Jun Zhao, Cupertino, CA (US); Rick J. Roberts, Sunnyvale, CA (US); Shulin Wang, Campbell, CA (US); Errol A. C. Sanchez, Tracy, CA (US); Aihua Chen, Cupertino, CA (US)

Correspondence Address: APPLIED MATERIALS, INC., PATENT COUNSEL, MS/2061, Legal Affairs Department, P.O. BOX 450A, Santa Clara, CA, 95052, US

(73) Assignee: Applied Materials, Inc.

(21) Appl. No.: 10/824,313

(22) Filed: Apr. 13, 2004

Related U.S. Application Data
(63) Continuation-in-part of application No. 10/428,374, filed on May 1, 2003.
(60) Provisional application No. 60/378,799, filed on May 8, 2002.

(51) Int. Cl. H01L 21/336; H01L 21/324

(52) U.S. Cl. 438/305; 438/400; 438/792; 438/798

(57) ABSTRACT

One embodiment of the present invention is a method for treating silicon nitride (SiₓN_{y}) films that includes electron beam treating the silicon nitride film.

This is a continuation-in-part of a patent application entitled “Methods and Apparatus for E-Beam Treatment Used to Fabricate Integrated Circuit Devices” having Ser. No. 10/428,374 that was filed on May 1, 2003, which patent application claimed the benefit of U.S. Provisional Application No. 60/378,799, filed on May 8, 2002, and which patent application is incorporated by reference herein.

### TECHNICAL FIELD OF THE INVENTION

One or more embodiments of the present invention pertain to methods for treating films such as, for example and without limitation, silicon nitride (“SiN”) films.

### BACKGROUND OF THE INVENTION

An article by S. Inaba et al. entitled “Increase of Parasitic Resistance of Shallow p+ Extension with SiN Sidewall Process by Hydrogen Passivation of Boron and Its Improvement by Preamorphization for Sub-0.25 μm pMOSFETs,” 1996 Symposium on VLSI Technology Digest of Technical Papers, 1996 discloses that fabrication of sub-0.25 μm pMOSFETs requires forming shallow p+ source/drain junctions at a depth of less than 100 nm with a low parasitic resistance, and that such junctions are formed using a gate sidewall and low energy BF₂ implantation of a p+ extension layer where silicon nitride (referred to therein as SiN) is used as a sidewall material (as being preferable to siO₂) to avoid lateral etching by HF cleaning in subsequent processing steps. The article also discloses that SiN sidewalls are also useful in gate self-aligned-contact processes. In addition, the article discloses that LP-CVD grown SiN (using Si₂H₆ and NH₃ precursors) contains hydrogen atoms that diffuse into the p+ extension layer to passivate B acceptors during activation by rapid thermal annealing (RTA), and that such passivation is problematic in that it results in high sheet resistance in the junction.

An article by M. Tanaka et al. entitled “Realization of High Performance Dual Gate DRAMs without Boron Penetration by Application of Tetrachlorosilane Silicon Nitride Films,” 2001 Symposium on VLSI Technology Digest of Technical Papers, 2001 disclosed that conventional silicon nitride (referred to therein as SiN) films accelerate boron penetration by its hydrogen desorption a during high temperature annealing process after SiN deposition. The article discloses that this is problematic since boron penetration causes depletion of gate electrodes and threshold voltage deviations, and thereby, degrades PMOSFETs. In addition, in next generation DRAMs, thick SiN films are used as a hard mask for self-align contact (“SAC”) processes to increase circuit density. The article further discloses that SiN films without boron penetration have to be developed for realization of dual gate CMOS systems with a SAC process. Finally, the article discloses that the content of SiH bonds in SiN films correlate with PMOS degradation, i.e., SiN induced boron penetration does not depend on either the total amount of hydrogen or NH content, but depends on SiH content so that it becomes worse in proportion to SiH content incorporated in SiN films. In essence, the article teaches that SiH bonds release hydrogen atoms more easily that NH bonds, i.e., SiN induced boron penetration is caused by hydrogen released from SiH bonds. Further, reduction of SiH content in SiN films is necessary to suppress SiN induced boron penetration, and the use of SiH-less films formed by tetrachlorosilane (TCS) and ammonia have successfully realized high performance of PMOSFETs.

In light of the above, there is a need to overcome one or more of the above-identified problems.

### SUMMARY OF THE INVENTION

One or more embodiments of the present invention advantageously overcome one or more of the above-identified problems. In particular, one embodiment of the present invention is a method for treating silicon nitride (SiₓN_{y}) films that comprises electron beam treating the silicon nitride film.

### BRIEF DESCRIPTION OF THE FIGURE

FIG. 1 shows a schematic diagram of a partial cross sectional view of an electron beam treatment apparatus that may be utilized to carry out one or more embodiments of the present invention;

FIG. 2 shows a fragmentary view of the electron beam treatment apparatus of FIG. 1 which helps to illustrate some details of its operation; and

FIG. 3 shows FTIR spectra of SiN films that were: (a) LPCVD deposited on wafers utilizing two different sets of precursors, and (b) e-beam treated in accordance with one or more embodiments of the present invention.

### DETAILED DESCRIPTION

We have discovered that an electron beam (or e-beam) treatment of silicon nitride films (i.e., SiₓN_{y} films, which are also referred to herein as SiN films) is effective in removing H from SiN films, for example and without limitation, by removing one or more of —H, N—H and —OH bonds. Such an e-beam treatment improves SiN films used, for example and without limitation, as a sidewall for a MOSFET gate region in FET fabrication. In addition, we have discovered that one or more embodiments of the present invention are advantageous in that one or more beneficial effects of removing H from SiN films can be provided in SiN films deposited using a number of different methods, for example and without limitation, in SiN films deposited using a Si₂Cl₆ precursor or a Si₂H₆ precursor. Still further, it is believed that the one or more beneficial effects of removing H from SiN films does not depend on type of process tool used to deposit the film, i.e., it does not depend on whether the process tool is a single chamber tool, a batch tool, or a mini-batch tool.

As used herein, the term electron beam or e-beam treatment refers to exposure of a film to a beam of electrons, for example, and without limitation, a relatively uniform beam of electrons. The e-beam may be scanned across a wafer, or the e-beam may be sufficiently broad to encompass a substantial portion, or the entirety, of a wafer (to achieve higher throughput processing it is advantageous to use a large-area or flood beam electron source, to expose the whole substrate simultaneously). The energy of the e-beam during the exposure is such that substantially an entire thickness of a layer of material is exposed to electrons from the e-beam, or predetermined portions of the layer beneath the surface of the layer are exposed to electrons from the e-beam. The exposure may also be accomplished in steps of varying energy to enable the whole layer, or portions of the layer to be exposed at predetermined depths.

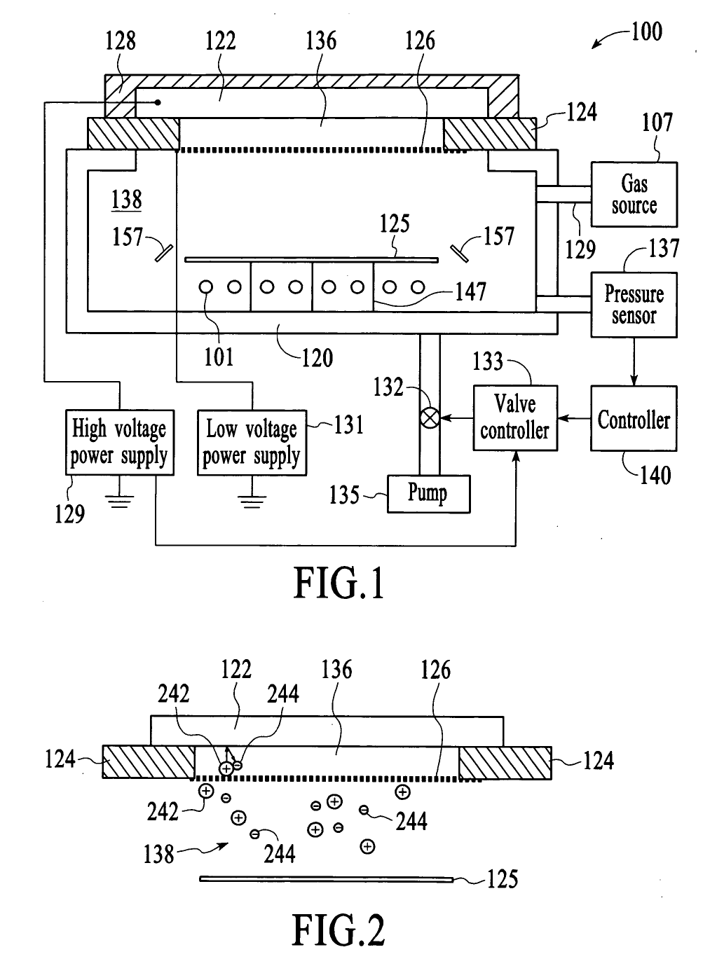

FIG. 1 shows a schematic diagram of a partial cross sectional view of large area electron beam source, electron beam treatment apparatus 100 (e-beam apparatus 100) that may be utilized to carry out one or more embodiments of the present invention. Such an e-beam treatment apparatus is available from Applied Materials, Inc. of Santa Clara, Calif. As shown in FIG. 1, e-beam apparatus 100 includes array 101 of quartz halogen lamps for heating a substrate or a wafer, which array is surrounded by heat shield 157 to provide substantial temperature uniformity across a wafer, for example and without limitation, temperature uniformity to within at least 8° C. It should be understood that mechanisms for heating the substrate or wafer are not limited to the use of lamps. In accordance with further embodiments of the present invention, instead of utilizing lamps for heating, the wafer or substrate may be disposed on a body that is referred to as a chuck or susceptor. In accordance with such embodiments, the chuck may be resistively heated in a manner that is well known to those of ordinary skill in the art to provide heating independent of that provided by the electron beam. In addition, the chuck may be an electrostatic check (for example, a monopolar or bipolar electrostatic chuck) to provide good contact between the wafer and the chuck. Many methods are well known to those of ordinary skill in the art for fabricating such electrostatic chucks. Further in accordance with such embodiments, a backside gas may be flown between the wafer and the chuck to enhance thermal conductivity between the two in a manner that is well known to those of ordinary skill in the art, such backside gas being flown in one or more zones depending on the need for controlling temperature uniformity. Still further in accordance with such embodiments, a cooling liquid may be flown inside the chuck to be able, for some treatment mechanisms, to reduce the temperature of the wafer in light of heating provided by the electron beam. Many methods are well known to those of ordinary skill in the art for flowing a cooling liquid through a chuck. Indeed, it should be understood that embodiments of the present invention are not limited to the use of the e-beam apparatus shown in FIG. 1, and that further embodiments of the present invention may be fabricated utilizing any one of a number of other technologies for developing suitable e-beams. However, SiN e-beam treatment using an apparatus of the type shown in FIG. 1 is advantageous because it involves a low thermal budget.

As further shown schematically in FIG. 1, substrate 125 is held over array 101 of lamps by pins 147, for example and without limitation, three (3) pins. In addition, such pins may include one or more thermocouples (not shown) to enable the temperature of substrate 125 to be monitored and controlled in accordance with any one of a number of mechanisms that are well known to those of ordinary skill in the art, for example and without limitation, using a chamber controller. In further addition, one of such pins may include a conductor to enable substrate 125 to be grounded. Pins 147 may be raised or lowered in a conventional matter, for example and without limitation, utilizing a lift plate assembly (not shown) to enable a conventional wafer transport robot and blade structure to move substrate 125 into and out of e-beam treatment apparatus 100.

Apparatus 100 is a type of e-beam apparatus like that disclosed in U.S. Pat. No. 5,003,178 (the '178 patent). Apparatus 100 utilizes various gases, and operates at various values of cathode voltage, gas pressure, and working distance (i.e., a distance between a cathode and anode in a generation and acceleration region of the electron beam treatment apparatus, to be described below). As will be described below, such gases and appropriate values of cathode voltage, gas pressure, and working distance may be determined readily by one of ordinary skill in the art without undue experimentation. Co-pending patent application entitled “Improved Large Area Source for Uniform Electron Beam Generation” filed Nov. 21, 2002, Ser. No. 10/301,508 (which co-pending patent application and the present patent application are commonly assigned) and the '178 patent are incorporated by reference herein.

As shown in FIG. 1, e-beam treatment apparatus 100 includes vacuum chamber 120; large-area cathode 122 (for example, and without limitation, a cathode having an area in a range from about 4 square inches to about 700 square inches); and anode 126. As further shown in FIG. 1, anode 126 is disposed between substrate 125 (located in ionization region 138) and cathode 122. Anode 126 is disposed at a working distance from cathode 122 that is determined in a manner to be described below.

As further shown in FIG. 1, electron source 100 further includes: (a) high-voltage insulator 124 that is disposed between cathode 122 and anode 126 and is operative to isolate cathode 122 from anode 126; (b) cathode cover insulator 128 that is located outside vacuum chamber 120 to provide electrical protection for users; (c) valved gas manifold 127 that has an inlet which is fabricated in accordance with any one of a number of methods that are well known to those of ordinary skill in the art to provide a mechanism for admitting gas into vacuum chamber 120 at one or more various input rates from gas source 107; (d) valve controller 133 that operates in response to signals from pressure sensor 137 and real time chamber controller 140 in a manner to be described below; (e) throttle valve 132 that operates in response to a signal from throttle valve controller 133 to control exhaust from vacuum chamber 120; (f) vacuum pump 135 (vacuum pump 135 may be any one or a number of commercially available vacuum pumps capable of pumping vacuum chamber 120 from atmospheric pressure to a pressure in a range between about 1 mTorr to about 200 mTorr such as, for example and without limitation, a turbo pump) that exhausts gas from chamber 120 through throttle valve 132 to control pressure inside vacuum chamber 120; (g) variable, high-voltage power supply 129 that is connected to cathode 122, and which supplies a signal to throttle valve controller 133 that provides a measure of e-beam current impinging upon substrate 125; and (h) variable, low-voltage power supply 131 that is connected to anode 126.

In accordance with one or more embodiments of the present invention, a high voltage (for example, a negative voltage between about −500 V and about −30 KV or higher) is applied to cathode 122 from variable, high-voltage power supply 129. In accordance with one embodiment of the present invention, high-voltage power supply 129 may be a Bertan Model #105-30R power supply manufactured by Bertan of Hicksville, N.Y., or a Spellman Model #SL30N-1200x258 power supply manufactured by Spellman High Voltage Electronics Corp. of Hauppage, N.Y. Variable, low-voltage power supply 131 (for example, a d.c. power supply capable of sourcing or sinking current) is utilized to apply a voltage to anode 126 that is positive relative to the voltage applied to cathode 122. For example, the voltage applied to anode 126 may range from about 0 V to about −500 V. In accordance with one embodiment of the present invention, low-voltage power supply 131 may be an Acopian Model #150PT12 power supply available from Acopian of Easton, Pa.

A wafer or substrate to be treated, such as substrate 125, is placed on pins 147. In accordance with one or more embodiments of the present invention, substrate 125 may be heated by a heating apparatus (for example and without limitation, a resistive heater disposed within a wafer or substrate holder in accordance with any one of a number of methods that are well known to those of ordinary skill in the art, or one or more infrared lamps such as array 101 of quartz halogen lamps) disposed to heat substrate 125 in accordance with any one of a number of methods that are well known to those of ordinary skill in the art. Some of the radiation output from lamps in an embodiment that utilizes lamps to provide heating may be reflected within chamber 120 to anode 126. Accordingly, in accordance with one or more such embodiments of the present invention, an internal portion of vacuum chamber 120 may be bead blasted, darkened, roughened, or anodized to reduce the coefficient of reflection of the internal portion of the chamber to be less than about 0.5. In this manner, a portion of the radiation output from the lamps may be absorbed by the internal portion of vacuum chamber 120.

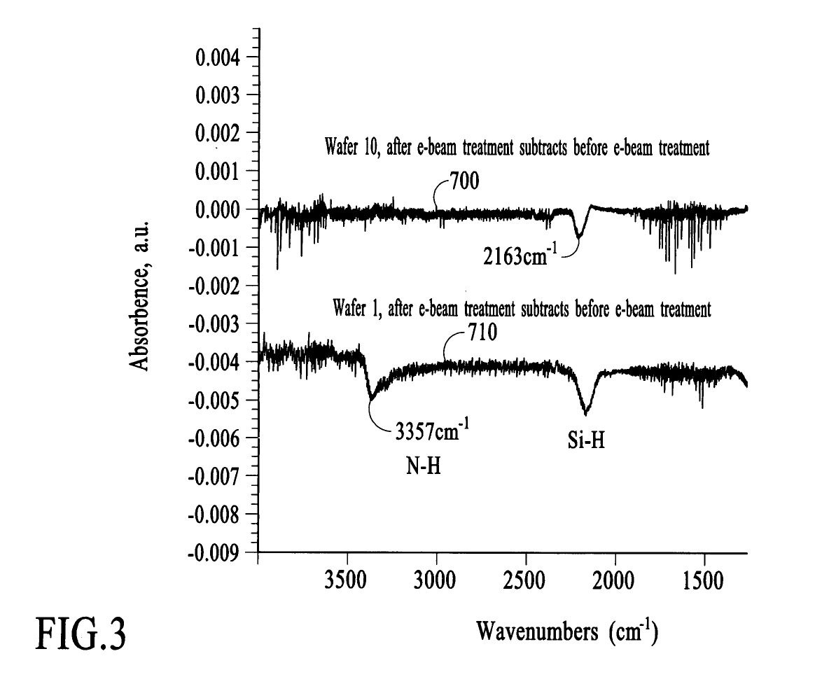

Wafer 125 may be placed at a relatively large distance, such as, for example, and without limitation, 10 to 30 mm, from anode 126 to prevent electrons from casting an image of anode 126 on wafer 125. In addition, irradiation of wafer 125 may further entail sweeping the electron beam back and forth across wafer 125 by using, for example and without limitation, a time-varying magnetic field produced by deflection coils surrounding vacuum chamber 120 as shown in FIG. 3 of the '178 patent.

In accordance with one or more embodiments of the present invention, anode 126 of electron beam treatment apparatus 100 may be fabricated (in whole or a surface thereof) from an electrically conductive material such as, for example, and without limitation, Al, Ti, Ni, Si, Mo, graphite, W, Co, and alloys of the foregoing. For treating films at relatively high temperatures, for example, temperatures in a range between about 200° C. and about 600° C., aluminum may provide a more suitable material than graphite. For example, aluminum generally has a higher thermal conductivity than graphite, and as a consequence, an anode formed from aluminum may bow less at high temperatures than one formed from graphite. In addition, aluminum has a lower emissivity than graphite, and this leads to lower heat transfer to the anode by radiation (for example, from wafer 125). In further addition, aluminum has a lower sputtering yield than graphite, thereby resulting in less contamination on wafer 125. It should be noted that in addition to anode 126 being made from aluminum, cathode 122 and vacuum chamber 122 may also be made from aluminum. However, the surface of cathode 122 may also be fabricated from Al, Ti, Ni, Si, Mo, graphite, W, Co and alloys of the foregoing.

Anode 126 may be, for example, and without limitation, a grid, a mesh or a plate having an array of holes disposed therethrough. For example, in accordance with one or more embodiments of the present invention, the size of the holes may be varied to compensate for a decrease in beam intensity that sometimes occurs at an edge of anode 126. In this manner, a more diametrically uniform electron beam may be generated. For example, in accordance with one or more embodiments of the present invention, anode 126 comprises 37,500 holes with four concentric zones of different hole diameter, providing approximately 58% open area. In using such an embodiment, electron beam uniformity may be tuned by hole diameter in each zone, with larger diameter holes disposed at the edge of at anode 126 where the tuning entails using film shrinkage uniformity. Examples for the array of holes and methods for making the holes are described in more detail in U.S. Pat. No. 6,407,399 which patent is incorporated by reference herein.

In some applications, it is desirable to provide constant electron beam current during treatment. The electron beam current may vary because, among other things, processing may cause deposition of outgassed treatment by-products on chamber walls, the anode, and the cathode, and this may reduce electron generation efficiency.

Apparatus 100 shown in FIG. 1 may provide constant electron beam current during treatment as follows: (a) high voltage power supply 129 and low voltage power supply 131 are set to predetermined output voltage values for a particular application (typically, the voltages are set in response to input from real time chamber controller 140 in a conventional manner); (b) valved gas manifold 127 is set to provide a predetermined value of gas flow for a particular application (typically, the setting of a valve is set in response to input from real time chamber controller 140 in a conventional manner); (c) throttle valve controller 133 sends a signal to throttle valve 132 to cause it to provide a predetermined gas pressure in vacuum chamber 120 for a particular application (typically, throttle valve controller 133 operates in response to input from real time chamber controller 140 in a conventional manner); (d) real time controller 140 sends a signal to throttle valve controller 133 that represents a “current set point” for a particular application; (e) high voltage power supply 129 sends a signal to throttle valve controller 133 that represents a measure of electron beam current; and (f) throttle valve controller 133 causes the measure of electron beam current to match the “current set point” by sending signals to throttle valve 132 to open it or close it to control chamber pressure so as to maintain constant beam current. For example and without limitation, in accordance with one embodiment of apparatus 100, throttle valve 132 has a response time for opening or closing of about 130 ms. Typically, as a chamber gets dirty, the efficiency of electron production goes down, and to counteract this, the chamber pressure is increased to provide a constant electron beam. In accordance with one or more embodiments, the measure of electron beam current is determined by estimating that, for example and without limitation, a predetermined number of electrons produced at cathode 122 do not travel through anode 126 (for example, anode 126 may include a pattern of holes that transmits only ˜60% of the electrons impinging thereon from cathode 122), and by estimating that a predetermined number of electrons (for example and without limitation, 10%) transmitted through anode 126 do not strike substrate 125 because the area anode 126 may be larger (for example and without limitation, 10% larger) than the area of substrate 125. As such, in accordance with one or more embodiments, the measure of electron beam current is determined by estimating that ˜40% of the electrons leaving cathode 122 (measured by high voltage power supply 129) reach substrate 125. Such estimates may be experimentally verified by measurements utilizing graphite wafers or by measurements utilizing a Faraday cup in accordance with any one of a number of methods that are well known to those of ordinary skill in the art.

In some applications, it may be desirable to provide constant beam current at different electron beam energies. For example it may be desirable to treat an upper layer of a film formed on a substrate, but not a bottom layer. This may be accomplished by utilizing an electron beam whose energy is low enough so that most of the electrons in the beam are absorbed in the upper layer. Subsequent to treating the upper layer, it may be desirable to treat lower layers of the film. This may be done by raising the accelerating voltage of the electron beam, i.e., the cathode voltage, to enable it to penetrate completely through the film.

FIG. 2 shows a fragmentary view of electron beam treatment apparatus 100 of FIG. 1 that helps to illustrate some details of its operation. To initiate electron emission in electron beam treatment apparatus 100, gas in ionization region 138 between anode 126 and wafer 125 must become ionized. In accordance with one or more embodiments of the present invention, the gas may include one or more of, for example, and without limitation, helium, argon, nitrogen, hydrogen, oxygen, ammonia, neon, krypton, and xenon. The step of ionizing the gas may be initiated by naturally occurring gamma rays, or it may be initiated by a high voltage spark gap disposed inside vacuum chamber 120 in accordance with any one of a number of methods that are well known to those of ordinary skill in the art.

Anode 126 is negatively biased by a voltage in a range, for example, from about 0 V to about −500 V that is applied thereto from low-voltage power supply 131. Once ionization is initialized, as shown in FIG. 2, positive ions 242 are attracted toward negatively biased anode 126. These positive ions 242 pass through holes in anode 126 into electron generation and acceleration region 136 between cathode 122 and anode 26. In region 136, positive ions 242 are accelerated toward cathode 122 as a result of a voltage (for example, a voltage in a range from about −500 V to about −30 KV or higher) that is applied thereto from high-voltage power supply 129. Upon striking the surface of cathode 122, positive ions 242 produce electrons 244 that are accelerated back toward anode 126. Some of electrons 244 strike anode 126, but many pass through anode 126, and continue on to impinge upon wafer 125. In addition, some of electrons 244 ionize gas molecules in ionization region 138.

The working distance between cathode 122 and anode 126 may be set to any value that is consistent with obtaining no arcing or breakdown in generation and acceleration region 136. This enables the presence of ions in generation and acceleration region 136 to be controlled by voltage applied to anode 126. In turn, this enables electron emission, and hence, electron beam current, to be controlled continuously from small currents to large currents by varying the voltage applied to anode 126. In addition, electron emission, and hence, electron beam current, can also be controlled by using throttle valve 132 to adjust the gas pressure in vacuum chamber 120 (i.e., raising or lowering gas pressure, raises or lowers, respectively, the number of ions in ionization region 138 and generation and acceleration region 136). As a result, in operation, one can utilize: (a) values of cathode voltage that are small enough to be useful in treating thin films; (b) values of gas pressure that are high enough to sustain electron beam current at such small values of cathode voltage; and (c) values of working distance that provide sufficient working tolerances to mitigate, for example, and without limitation, mechanical problems that might be caused by heating of chamber elements such as anode 126.

One can determine appropriate values of operation by routine experimentation as follows. First, chose a convenient working distance for the electron beam treatment apparatus. Next, select a value of cathode voltage that is determined by the energy of electrons required to treat a wafer. Next, while measuring the electron beam current (using, for example, a current detector disposed in series with high-voltage power supply 129), vary the gas pressure to sustain an effective, uniform electron beam. The current is measured to determine values of current that provide useful throughput (for example, and without limitation, electron beam current may range from about 1 mA to about 40 mA), and to ensure that the values of cathode voltage, gas pressure, and working distance used do not result in arcing or breakdown in generation and acceleration region 138 (breakdown may be evidenced by a faint plasma or arcing which can also be observed by voltage or current spiking at the cathode).

It is believed that the combination of large area electron beam irradiation, and raising the temperature of the treated film in applications where such is the case, increases electron beam conductivity of insulation layers which dissipate charge build-up created by the impinging electron beam. It is believed that this enables treatment without inducing electron traps or positive charge build-up in the layers. In addition, it is believed that the e-beam induced conductivity effect is dependent on substrate temperature (becoming more conductive with increasing temperature). This is may be taken in to account in developing e-beam treatment recipes to ensure that one does not create static charge.

As shown in FIG. 1, array of lamps 101 irradiate and heat wafer or substrate 125, thereby controlling its temperature. Since wafer 125 is in a vacuum environment, and is thermally isolated, wafer 125 can be heated or cooled by radiation. If the lamps are extinguished, wafer 125 will radiate away its heat to the surrounding surfaces and gently cool. Wafer 125 is simultaneously heated by the lamps and irradiated by the electron beam throughout the entire process. For example, in accordance with one embodiment, array 101 of infrared quartz halogen lamps are on continuously until the temperature of wafer 125 reaches a process operating temperature. The lamps are thereafter turned off and on at a predetermined, and perhaps, varying duty cycle to control the wafer temperature.

We have formed SiN films on wafers using: (a) hexachlorodisilane (Si₂Cl₆) and ammonia (NH₃) precursors in a low atmosphere, chemical vapor deposition (“LACVD”) process tool and (b) disilane (Si₂H₆) and NH₃ in an LACVD process tool. We then e-beam treated such wafers in accordance with one or more embodiments of the present invention using an e-beam treatment apparatus like apparatus 100 shown in FIG. 1. FIG. 3 shows difference FTIR spectra 700 and 710. To form a difference FTIR spectrum, an FTIR spectrum obtained after e-beam treatment is subtracted from an FTIR spectrum obtained prior to e-beam treatment—this enables the FTIR spectrum obtained prior to e-beam treatment to serve as a measure of background. Using such a technique, a negative peak in a spectrum shown in FIG. 3 means that a species corresponding to the negative peak has been removed from the film. Difference FTIR spectrum 700 shown in FIG. 3 relates to an SiN film that was produced by LACVD using a disilane precursor at process conditions (for example, at a temperature of about 530° C.) leading to a film growth rate of about 150 Å/min, and FTIR spectrum 710 shown in FIG. 3 relates to an SiN film that was produced by LACVD using a hexachlorodisilane precursor at process conditions (for example, at a temperature of about 530° C.) leading to a film growth rate of about 100 Å/min. Both SiN films were treated in using an e-beam treatment apparatus like apparatus 100 shown in FIG. 1 wherein the cathode voltage was about 8 kev, the wafer temperature was about 400° C., the ambient gas in the chamber was argon (Ar), the e-beam dose was about 7500 μC/cm² (e-beam dose is the integral of current over time divided by wafer area where, for a constant current, dose is the electron beam current multiplied by time of treatment and divided by wafer area) utilizing a substantially constant electron beam current, the chamber pressure was about 30 mTorr, and the e-beam treatment lasted from about 3 to about 5 minutes. As one can readily appreciate from FIG. 3, Si—H bonds have been removed from the SiN films. In addition, N—H bonds have also been removed to a certain extent depending on the SiN deposition process.

It should be understood that further embodiments of the present invention for electron beam treating silicon nitride (SiₓN_{y}) films include heating the SiN films in a temperature range from about room temperature to about 700° C., and exposing the SiN films to e-beam current in doses in a range from about 100 μC/cm² to about 10000 μC/cm². One of ordinary skill in the art can determine appropriate temperatures, e-beam dose, and acceleration energy routinely without undue experimentation to provide an effective amount of H removal for any suitable thickness of film. For example and without limitation, for thick films, the electron beam dose may be divided into treatment periods that correspond to steps of decreasing voltage which provides a substantially uniform dose process in which the SiN film is cured, for example, from the bottom up. Thus, the depth of electron beam penetration may be varied during the treatment process. In addition, various ambient gases (for example, one or more gases set forth above) may also be determined by one of ordinary skill in the art routinely without undue experimentation to provide effective treatment in a particular case. In further addition, various pressures may be utilized, consistent with the discussion above, to provide arc-free treatment periods and relatively constant electron-beam current during treatment periods.

The length of the e-beam treatment may range from about 0.5 minute to about 120 minutes, and as those of ordinary skill in the art can readily appreciate, the length of e-beam treatment may depend one or more of the above-identified parameters, and that particular sets of parameters can be determined routinely without undue experimentation in light of the detailed description presented herein.

In some e-beam treatment applications, it may be desirable to provide a constant beam current at different electron beam energies. For example it may be desirable to expose or cure an upper layer of a film, but not a lower or bottom layer. This can be done by utilizing an electron beam energy low enough such that most of the electrons are absorbed in the upper layer of the film. Subsequent to treating the upper layer, it may be desirable to treat a deeper layer of the film. This can be done by raising the accelerating voltage of the electron beam to penetrate to the deeper layer. It may be desirable in performing these exposures to be able to alter the accelerating voltage without causing a change in the emission current. However, if the accelerating voltage is increased it tends to cause more ionization and therefore an increase in beam current. Similarly if the accelerating voltage is lowered, ionization lessens and the beam current is decreased. In accordance with one or more such applications in which a constant beam current is maintained independent of changes in accelerating voltage, the beam current may be sampled via a sensor. An output from the sensor may be used to control voltage on grid anode 26 such that an increase in beam current will cause a decrease in bias voltage on grid 26 and a decrease in emission current from cathode 26. The output from the sensor may be adjusted so that any change in current caused by a change in the accelerating voltage is counteracted by a change in bias voltage to maintain the beam current reaching the target constant. Alternatively, an output from the sensor can be used to counteract changes in emission current by raising or lowering the pressure in ionization region 138.

The total treatment by electrons at a selected level is controlled by the beam current and exposure time. In effect, control of dose and beam energy provides selective control of treatment at selected depths in the target.

Process conditions for e-beam treatment include the following. The pressure in vacuum chamber 20 may vary in a range of from about 10⁻⁵ to about 10² Torr, and preferably in a range of from about 10⁻³ to 10⁻¹ Torr. The distance between substrate 27 and grid anode 26 should be sufficient for some electrons to generate ions in their transit between grid anode 26 and the surface of substrate 125. The temperature of substrate 125 may vary in a range from about 0° C. to about 1050° C. The electron beam energy may vary in a range from about 0.1 to about 100 KeV. The total dose of electrons may vary in a range from about 1 to about 100,000 μC/cm². The dose and energy selected will be proportional to the thickness of the films to be treated. The gas ambient in e-beam tool apparatus may be any of the following gases: nitrogen, oxygen, hydrogen, argon, helium, ammonia, silane, xenon or any combination of these gases. The electron beam current may vary in a range from about 0.1 to about 100 mA. Preferably, the e-beam treatment is conducted with a wide, large beam of electrons from a uniform large-area electron beam source which covers the surface area of the film to be treated. In addition, for thick films, the electron beam dose may be divided into steps of decreasing voltage which provides a uniform dose process in which the material is cured from the bottom up. Thus, the depth of electron beam penetration may be varied during the treatment process. The length of the treatment may range from about 0.5 minute to about 120 minutes. As those of ordinary skill in the art can readily appreciate, the length of e-beam treatment may depend one or more of the above-identified parameters, and that particular sets of parameters can be determined routinely without undue experimentation in light of the detailed description presented herein.

In light of the above, an SiN sidewall spacer process used to fabricate a pMOSFET semiconductor circuit in accordance with one or more embodiments of the present invention includes steps of: (a) gate oxidation utilizing any one of a number of methods that are well known to those of ordinary skill in the art; (b) gate electrode formation utilizing any one of a number of methods that are well known to those of ordinary skill in the art; (c) shallow source/drain extension ion implantation utilizing any one of a number of methods that are well known to those of ordinary skill in the art; (d) SiN gate sidewall formation utilizing any one of a number of methods that are well known to those of ordinary skill in the art; (e) source/drain deep junction ion implantation utilizing any one of a number of methods that are well known to those of ordinary skill in the art; and (f) activation of source/drain utilizing any one of a number of methods that are well known to those of ordinary skill in the art such as, for example and without limitation, rapid thermal annealing.

One or more further embodiments of the present invention relate to the use of SiN films as a pre-metal deposition (“PMD”) etch stop used in providing metal contacts to the source/drain and gate. For example, such a PMD SiN layer may also include a number of hydrogen bonds which may degrade gate oxide performance. In accordance with one or more further embodiments of the present invention, such a PMD etch stop later is e-beam treated to remove hydrogen bonds.

Those skilled in the art will recognize that the foregoing description has been presented for the sake of illustration and description only. As such, it is not intended to be exhaustive or to limit the invention to the precise form disclosed. For example, although certain dimensions were discussed above, they are merely illustrative. In addition, the term substrate includes those suitable to be processed into an integrated circuit or other microelectronic device, and is used in the broadest sense of the word. The term substrates also include glass substrates of any kind.

What is claimed is:

1. A method for treating silicon nitride (SiₓN_{y}) films that comprises:
electron beam treating the silicon nitride film.

2. The method of claim 1 which further comprises heating the film to a temperature in a range from about room temperature to about 700° C.

3. The method of claim 1 wherein the step of electron beam treating includes exposing the film to electron beam current at doses in a range from about 100 μC/cm² to about 10000 μC/cm².

4. The method of claim 1 wherein the step of electron beam treating further includes exposing the film from about 0.5 minute to about 120 minutes.

5. The method of claim 1 wherein the step of electron beam treating comprises placing the film in an ambient gas in a chamber wherein an electron beam is formed between a cathode and an anode, and providing a cathode voltage in range from about −0.5 KV to about −10 KV.

6. The method of claim 5 wherein the ambient gas is one or more of: Ne, He, Ar, H₂, O₂, Kr, Xe, and N₂.

7. The method of claim 5 wherein a pressure of the ambient gas in the chamber and a working distance between the cathode and the anode are maintained so that arcing does not occur between the cathode and the anode.

8. The method of claim 5 wherein the pressure of the ambient gas in the chamber is maintained at one or more levels that provide a substantially constant electron beam current during at least one treatment period.

9. A method for fabricating a pMOSFET that comprises steps of:
oxidizing a gate;
forming a gate electrode;
implanting to form shallow source/drain extensions;
forming a SiN gate sidewall;
implanting to form source/drain deep junctions; and
activating the source/drain.
